(19) United States
(12) Patent Application Publication
(10) Pub. No.: US 2007/0141396 A1
(43) Pub. Date: Jun. 21, 2007

(54) Organic luminescence display device and method of manufacturing the same

(76) Inventors: Min-Seung Chun, Suwon-si (KR); Mi-Kyung Kim, Suwon-si (KR); Dong-Hun Kim, Suwon-si (KR); Jung-Ha Son, Suwon-si (KR); Jae-Hyun Kwak, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/599,132

(22) Filed: Nov. 13, 2006

(30) Foreign Application Priority Data
Dec. 20, 2005 (KR) 10-2005-0126101
Dec. 26, 2005 (KR) 10-2005-0129922

(51) Int. Cl. H01L 51/54; H01L 51/52

(52) U.S. Cl. 428/690; 428/917; 313/504; 313/506; 257/E51.05; 427/66

(57) ABSTRACT

An organic luminescence display device having an emission layer between a first electrode and a second electrode is disclosed. One embodiment of the device includes: a first hole injection layer and a second hole injection layer between the first electrode and the emission layer; and a charge generation layer doped with a p-type dopant between the first hole injection layer and the second hole injection layer. The device has a reduced driving voltage and an enhanced efficiency and lifetime.

### CROSS-REFERENCE TO RELATED APPLICATIONS

This application claims the benefit of Korean Patent Application Nos. 10-2005-0126101, filed on Dec. 20, 2005 and 10-2005-0129922, filed on Dec. 26, 2005, in the Korean Intellectual Property Office, the disclosures of which are incorporated herein in their entireties by reference.

### BACKGROUND

1. Field

The present disclosure relates to an organic luminescence display device and a method of manufacturing the same, and more particularly, to an organic luminescence display device having a charge generation layer, and a method of manufacturing the same.

2. Description of the Related Technology

Electroluminescent (EL) devices, which are self-emissive display devices, have drawn attention for their advantages such as a wide viewing angle, high contrast, and a short response time. EL devices are classified into inorganic EL devices and organic EL devices according to materials used to form emission layers of the EL devices. Organic EL devices have good brightness and driving voltage, and a short response time. Organic EL devices can also display multiple color images.

In general, organic luminescence display devices have an anode formed on a substrate. Organic EL devices also include a hole transport layer (HTL), an emission layer (EML), an electron transport layer (ETL) and a cathode sequentially stacked over the anode. Here, the HTL, EML and ETL include organic thin films formed of organic compounds.

The organic EL device described above may be operated as follows. A voltage is applied between the anode and the cathode. Then, holes are injected from the anode to the emission layer via the hole transport layer. Electrons are injected to the emission layer via the electron transport layer from the cathode. The electrons and holes recombine with each other in the emission layer, thereby forming excitons having an excited energy state. The excitons, while returning from the excited state to a ground state, cause fluorescent molecules of the emission layer to emit light.

In top-emission type organic luminescence display devices, the thicker the device profile is, the better the microcavity effect is. The microcavity effect refers to a phenomenon that a wavelength of light emitting from a display device depends on a path along which the light travels within the device. In addition, a device with a thick profile may minimize image defects caused by particles.

However, as the total thickness of the device increases, an increase in driving voltage, which can be a problem, occurs. To maximize its efficiency, there is a need to provide a suitable light path which permits light to have a wavelength closest to its original wavelength. The light path may be adjusted by changing the thickness of an organic layer of the device. In general, the thicker the organic layer is, the longer a light wavelength is. The thickest portion of the organic layer is a red (R) emission layer, and the thinnest portion of the organic layer is a blue (B) emission layer. The range of the thickness has a preferable period thickness and a maximum light extraction efficiency can be obtained. A one-period thickness is too thin to prevent a poor emission due to particles. A two-period thickness is too thick to prevent an increase in the driving voltage even though the two-period thickness may prevent a poor emission due to particles.

### SUMMARY

One aspect of the invention provides an organic luminescence display device comprising: a first electrode; a second electrode; an emission layer interposed between the first and second electrodes; a first hole injection layer interposed between the first electrode and the emission layer; a second hole injection layer interposed between the first hole injection layer and the emission layer; and a charge generation layer interposed between the first hole injection layer and the second hole injection layer, the charge generation layer being doped with a p-type dopant.

The charge generation layer may comprise a compound represented by Formula 1:

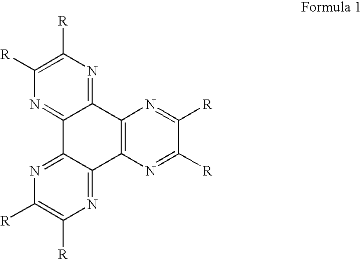

wherein R is a nitrile (—CN) group; a sulfone (—SO₂R′) group, a sulfoxide (—SOR′) group, a sulfoneamide (—SO₂NR′₂) group, a sulfonate (—SO₃R′) group, a nitro (—NO₂) group, or a trifluoromethyl (—CF₃) group; and wherein R′ is an alkyl group, aryl group, or heterocyclic group that has 1-60 carbon atoms and is unsubstituted or substituted with amine, amide, ether, or ester.

The p-type dopant may comprise at least one selected from the group consisting of hexanitrile hexaazatriphenylene, tetrafluoro-tetracyanoquinodimethane (F₄-TCNQ), FeCl₃, F₁₆CuPc and a metal oxide. The metal oxide may comprise at least one selected from the group consisting of vanadium oxide (V₂O₅), rhenium oxide (Re₂O₇), and indium tin oxide (ITO). The p-type dopant may have a lowest unoccupied molecular orbital (LUMO) energy level. At least one of the first and second hole injection layers may comprise a material having a highest occupied molecular orbital (HOMO) energy level. A difference between the lowest unoccupied molecular orbital (LUMO) energy level of the p-type dopant and the highest occupied molecular orbital (HOMO) energy level of the material of the at least one of the first and second hole injection layers may be between about −2 eV and about +2 eV.

The device may comprise a plurality of pixels, and the charge generation layer may form a common layer for at least two of the pixels. The charge generation layer may have a thickness of about 10 Å to about 200 Å. The charge generation layer may have a thickness of about 20 Å to about 80 Å.

The organic luminescence display device may further comprise a hole transport layer interposed between the first electrode and the emission layer, and at least one of a hole blocking layer, an electron transport layer and an electron injection layer interposed between the emission layer and the second electrode. The organic luminescence display device may further comprise an electron transport layer interposed between the second electrode and the emission layer. The organic luminescence display device may further comprise a substrate, wherein the first electrode is formed over the substrate. The organic luminescence display device may further comprise an electron injection layer interposed between the electron transport layer and the second electrode. The organic luminescence display device may further comprise a hole blocking layer interposed between the electron transport layer and the emission layer.

Another aspect of the invention provides an electronic device comprising the organic luminescence display device described above.

Yet another aspect of the invention provides a method of manufacturing an organic luminescence display device, the method comprising: forming a first hole injection layer over a first electrode; forming a charge generation layer over the first hole injection layer, the charge generation layer being doped with a p-type dopant; and forming a second hole injection layer over the charge generation layer.

The method may further comprise: forming an emission layer over the second hole injection layer; and forming a second electrode over the emission layer. The method may further comprise: forming a hole transport layer after forming the second hole injection layer and before forming the emission layer; and forming at least one of a hole blocking layer, an electron transport layer, and an electron injection layer after forming the emission layer and before forming the second electrode.

The charge generation layer may comprise a compound represented by Formula 1:

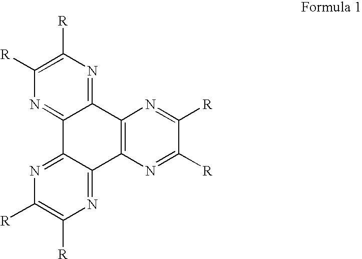

wherein R is a nitrile (—CN) group, a sulfone (—SO₂R′) group, a sulfoxide (—SOR′) group, a sulfoneamide (—SO₂NR′₂) group, a sulfonate (—SO₃R′) group, a nitro (—NO₂) group, or a trifluoromethyl (—CF₃) group; and wherein R′ is an alkyl group, aryl group, or heterocyclic group that has 1-60 carbon atoms and is unsubstituted or substituted with amine, amide, ether, or ester.

The p-type dopant may comprise at least one selected from the group consisting of hexanitrile hexaazatriphenylene, tetrafluoro-tetracyanoquinodimethane (F₄-TCNQ), FeCl₃, F₁₆CuPc and a metal oxide. The metal oxide may be at least one selected from the group consisting of vanadium oxide (V₂O₅), rhenium oxide (Re₂O₇), and indium tin oxide (ITO). The p-type dopant may have a lowest unoccupied molecular orbital (LUMO) energy level. At least one of the first and second hole injection layers may comprise a material having a highest occupied molecular orbital (HOMO) energy level. A difference between the lowest unoccupied molecular orbital (LUMO) energy level of the p-type dopant and the highest occupied molecular orbital (HOMO) energy level of the material of the at least one of the first and second hole injection layers may be between about −2 and about +2 eV.

Forming the charge generation layer may comprise using resistance heating vapor deposition, electron beam vapor deposition, laser beam vapor deposition, or sputtering deposition. The charge generation layer may have a thickness of about 10 Å to about 200 Å.

Another aspect of the invention provides an organic luminescence display device having a reduced driving voltage and a method of manufacturing the same.

Another aspect of the invention provides an organic luminescence display device having an emission layer between a first electrode and a second electrode, the device comprising: a first hole injection layer and a second hole injection layer between the first electrode and the emission layer; and a charge generation layer, which is doped with a p-type dopant, between the first hole injection layer and the second hole injection layer.

Yet another aspect of the invention provides a method of manufacturing an organic luminescence display device having an emission layer between a first electrode and a second electrode, the method comprising: forming a first hole injection layer on the first electrode; forming a charge generation layer that is doped with a p-type dopant on the first hole injection layer; and forming a second hole injection layer on the charge generation layer.

### BRIEF DESCRIPTION OF THE DRAWINGS

The above and other aspects of the invention will become more apparent by describing in detail exemplary embodiments thereof with reference to the attached drawings in which:

FIG. 1 is a cross-sectional view of an organic luminescence display device; and

FIGS. 2A through 2C are cross-sectional views illustrating a method of manufacturing an organic luminescence display device according to an embodiment.

### DETAILED DESCRIPTION OF CERTAIN INVENTIVE EMBODIMENTS

Hereinafter, the instant disclosure will be described in detail by explaining certain inventive embodiments with reference to the attached drawings.

An organic electroluminescent (EL) display device having an emission layer between a first electrode and a second electrode according to an embodiment includes a first hole injection layer and a second hole injection layer between the first electrode and the emission layer. The organic EL device may include a charge generation layer between the first hole injection layer and the second hole injection layer. The charge generation layer may be doped with a p-type dopant.

The charge generation layer according to an embodiment may include a compound represented by Formula 1:

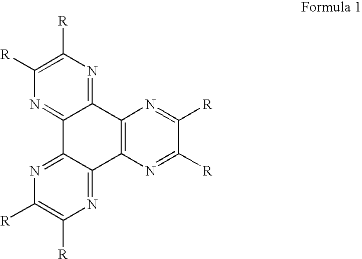

In Formula 1, R is a nitrile (—CN) group, a sulfone (—SO₂R′) group, a sulfoxide (—SOR′) group, a sulfoneamide (—SO₂NR′₂) group, a sulfonate (—SO₃R′) group, a nitro (—NO₂) group, or a trifluoromethyl (—CF₃) group (where R′ is an alkyl group, aryl group, or heterocyclic group that has 1-60 carbon atoms and is unsubstituted or substituted with amine, amide, ether, or ester). Examples of the compound of Formula 1 include, but are not limited to, compounds represented by the following formulas:

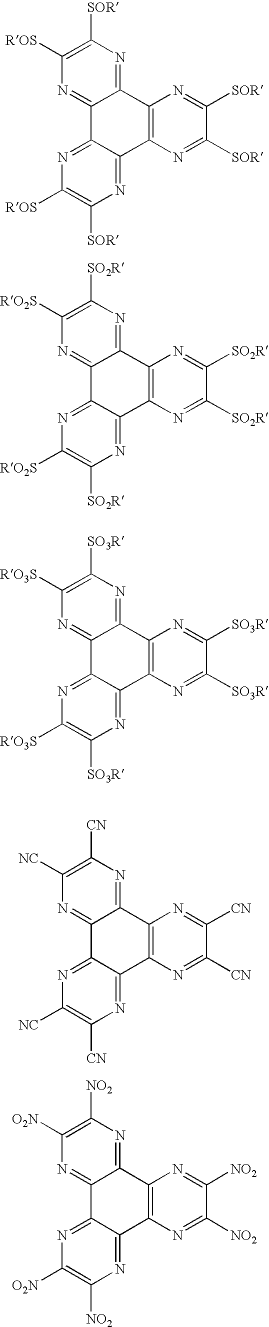

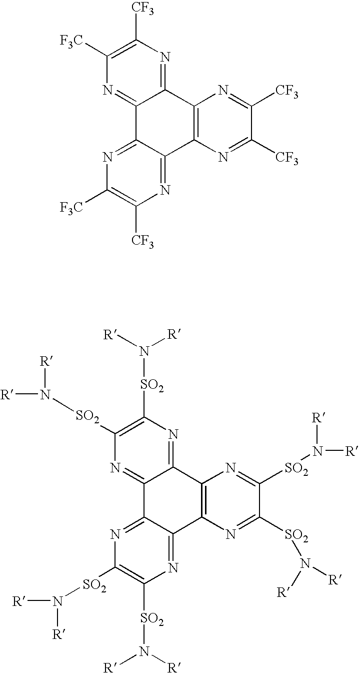

In the above formulas, R′ is an alkyl group, aryl group, or heterocyclic group that has 1-60 carbon atoms and is unsubstituted or substituted with amine, amide, ether, or ester. Organic materials for forming the charge generation layer represented by the above formulas are for illustrative purposes only, but are not limited thereto.

The p-type dopant in the charge generation layer may be one selected from hexanitrile hexaazatriphenylene, tetrafluoro-tetracyanoquinodimethane (F₄-TCNQ), FeCl₃, F₁₆CuPc and a metal oxide. The metal oxide may be vanadium oxide (V₂O₅), rhenium oxide (Re₂O₇), or indium tin oxide (ITO).

The p-type dopant material may be a material having an energy level different from that of a material for the first and/or second hole injection layers. A difference between a lowest unoccupied molecular orbital (LUMO) energy level of the p-type dopant material and a highest occupied molecular orbital (HOMO) energy level of the material for the first hole injection layer and/or the second hole injection layer may be from about −2 eV to about +2 eV.

For example, hexaazatriphenylene has a HOMO energy level of about 9.6 eV to about 9.7 eV, and a LUMO energy level of about 5.5 eV. In addition, tetrafluoro-tetracyanoquinodimethane (F₄-TCNQ) has a HOMO energy level of about 8.53 eV, and a LUMO energy level of about 6.23 eV. The first and second hole injection layer material used in the organic luminescent display device according to the current embodiment has a HOMO energy level of about 4.5 eV to about 5.5 eV. Accordingly, when hexaazatriphenylene is used as the p-type dopant material, the difference between the LUMO energy level of the charge generation layer and the HOMO energy level of the first hole injection layer material or the second hole injection layer material is about −1.0 eV to 0 eV. In addition, when tetrafluoro-tetracyanoquinodimethane (F4-TCNQ) is used as the p-type dopant material in the charge generation layer, the difference between the LUMO energy level of the charge generation layer and the HOMO energy level of the first hole injection layer or the second hole injection layer is about −0.73 to about 1.73 eV.

By forming the charge generation layer between the first hole injection layer and the second hole injection layer using the charge generating material, driving voltage of the organic luminescent display device can be reduced.

According to an embodiment, the charge generation layer can be formed using resistance heating vapor deposition, electron beam vapor deposition, laser beam vapor deposition, sputtering deposition or the like. The charge generation layer can be formed of a compound represented by Formula 1 in which R′ in Formula 1 is a C₅-C₆₀ alkyl group unsubstituted or substituted with amine, amide, ether, or ester. The charge generation layer may be formed by ink-jet printing, spin coating, doctor blading, roll coating or the like. In these methods, the charge generation layer is formed using a solution instead of using a vapor deposition method.

In one embodiment, the charge generation layer can form a common layer for each of a plurality of pixels. The charge generation layer may have a thickness of about 10 Å to about 200 Å, and optionally about 20 to about 80 Å. When the thickness of the charge generation layer is less than 10 Å, a charge generating effect is lower. When the thickness of the generation layer is greater than 200 Å, driving voltage is increased or cross-talk due to a leakage current can occur.

The organic luminescence display device according to the current embodiment may further include a hole transport layer between the first electrode and the emission layer. The device may also include at least one of a hole blocking layer, an electron transport layer and an electron injection layer between the emission layer and the second electrode.

According to another embodiment, there is provided a method of manufacturing an organic luminescence display device having an emission layer between a first electrode and a second electrode. The method includes: forming a first hole injection layer on the first electrode; forming a charge generation layer doped with a p-type dopant on the first hole injection layer; and forming a second hole injection layer on the charge generation layer. The method of manufacturing the organic luminescence display device according to the current embodiment will now be described in detail.

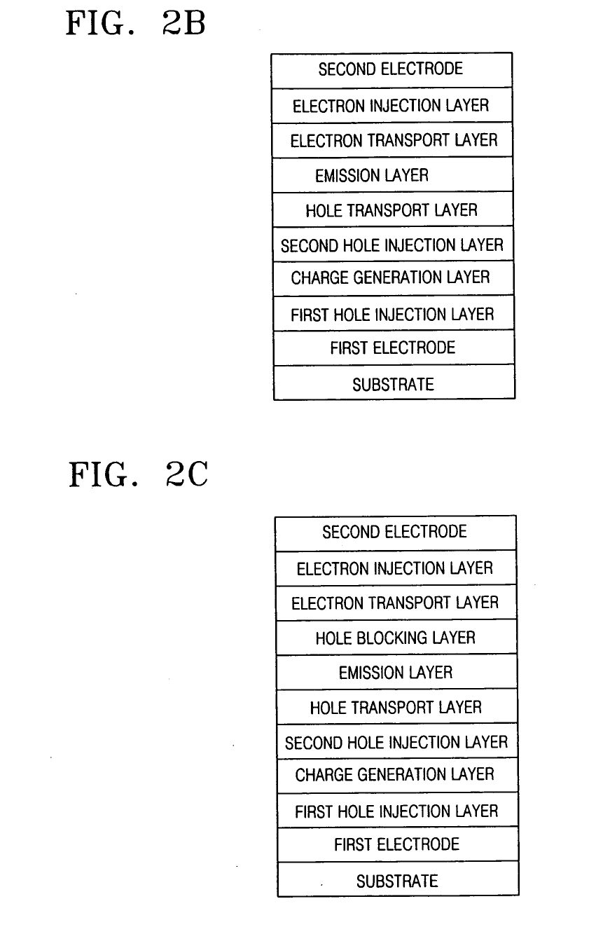

FIGS. 2A through 2C illustrate a method of manufacturing an organic luminescence display device according to an embodiment. First, a material for an anode (a first electrode), is deposited on a substrate to form the anode. Here, any substrate suitable for an organic luminescence display device may be used as a substrate. Examples of the substrate may include, but are not limited to, a glass or transparent plastic substrate that has good transparency, surface smoothness, ease of handling and water-proofness. The anode material may include a high work function metal (≧ about 4.5 eV), or indium tin oxide (ITO), indium zinc oxide (IZO), tin oxide (SnO2), zinc oxide (ZnO) or the like that are transparent and highly conductive.

A first hole injection (HIL) layer may be formed on the anode. The first hole injection layer can be formed by thermally evaporating a material for the hole injection layer in a high vacuum. In other embodiments, the material may be used in a form of solution. In such embodiments, the layer may be formed by spin-coating, dip-coating, doctor-blading, inkjet printing, or thermal transfer, organic vapor phase deposition (OVPD) or the like.

The first hole injection layer (HIL) may be formed using vacuum thermal deposition, spin coating or the like as described above. The thickness of the first hole injection layer may be about 100 Å to about 1,500 Å. When the thickness of the first hole injection layer is less than 100 Å, the hole injection characteristic deteriorates. When the thickness of the first hole injection layer is greater than 1,500 Å, driving voltage is increased. In one embodiment for top emission type organic luminescence display devices, the thickness of the first hole injection layer may be in a range of about 1,000 to about 1,500 Å.

Examples of the material for the first hole injection layer include, but are not limited to, copper phthalocyanine (CuPc) or starburst-type amine series such as TCTA, m-MTDATA, IDE406 (available from Idemitsu Kosan Co., Ltd, Tokyo, Japan) and the like. Below are the chemical formulas of CuPc, TCTA, and m-MTDATA.

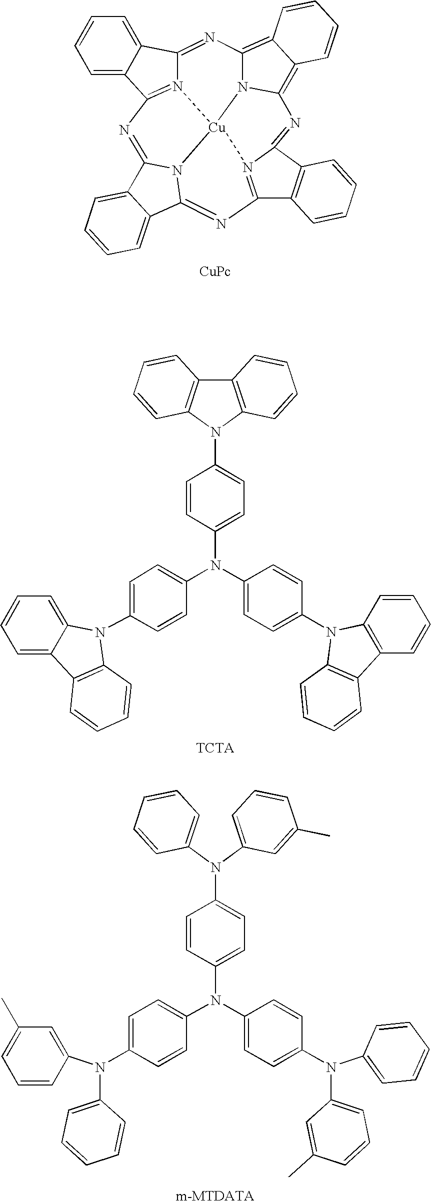

A charge generation layer may be formed on the first hole injection layer. The material for forming the charge generation layer may be, but is not limited to, a compound represented by Formula 1 as follows:

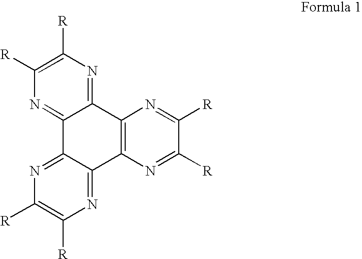

In Formula 1, R is a nitrile (—CN) group, a sulfone (—SO₂R′) group, a sulfoxide (—SOR′) group, a sulfoneamide (—SO₂NR′₂) group, a sulfonate (−SO₃R′) group, a nitro (—NO₂) group, or a trifluoromethyl (—CF₃) group. R′ is an alkyl group, aryl group, or heterocyclic group that has 1-60 carbon atoms and is unsubstituted or substituted with amine, amide, ether, or ester.

The charge generation layer may be doped with a p-type dopant. The p-type dopant can be at least one of hexanitrile hexaazatriphenylene, tetrafluoro-tetracyanoquinodimethane (F₄-TCNQ), FeCl₃, F₁₆CuPc and a metal oxide. The metal oxide may be vanadium oxide (V₂O₅), rhenium oxide (Re₂O₇), or indium tin oxide (ITO).

The charge generation layer can be formed by depositing a material for the charge generation layer on the first hole injection layer using resistance heating vapor deposition, electron beam vapor deposition, laser beam vapor deposition, sputtering or the like. The charge generation layer can form a common layer for a plurality of pixels. The charge generation layer may have a thickness of about 10 Å to about 200 Å, and optionally about 20 Å to about 80 Å. When the thickness of the charge generation layer is less than 10 Å, a charge generating effect is reduced. When the thickness of the charge generation layer is greater than 200 Å, driving voltage is increased.

A second hole injection layer (HIL) may be formed by depositing a second hole injection layer material on the charge generation layer. The second HIL may be formed using various methods, such as vacuum thermal deposition, spin coating or the like. The material for the second hole injection layer is not particularly limited, but may be the same material as that used for the first hole injection layer. The thickness of the second hole injection layer may be about 50 Å to about 1,000 Å. When the thickness of the second hole injection layer is less than 50 Å, a hole transporting characteristic deteriorates. When the thickness of the second hole injection layer is greater than 1,000 Å, driving voltage is increased.

A hole transport layer (HTL) may be optionally formed by depositing a hole transport layer material on the second hole injection layer. The HTL may be formed using various methods, such as vacuum thermal deposition, spin coating or the like. Examples of the hole transport layer material include, but are not limited to, N,N′-bis(3-methylphenyl)-N,N′-diphenyl-[1,1-biphenyl]-4,4′-deamine(TPD), N,N′-di(naphthalene-1-yl)-N,N′-diphenyl benzidine(α-NPD), IDE 320 (available from Idemitsu Kosan Co., Ltd.) and the like. The thickness of the hole transport layer may be about 50 Å to about 500 Å. When the thickness of the hole transport layer is less than 50 Å, a hole transporting characteristic deteriorates. When the thickness of the hole transport layer is greater than 500 Å, driving voltage is increased.

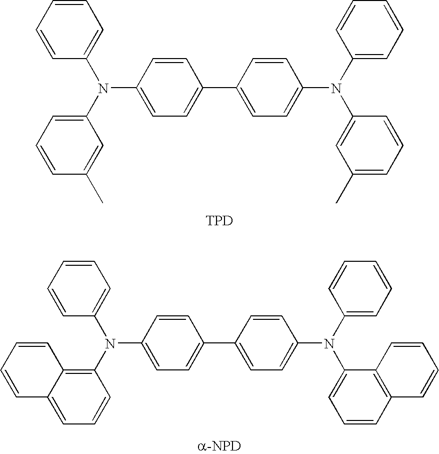

An emission layer (EML) may be formed on the hole transport layer. The method of forming the emission layer is not particularly limited, and various methods such as vacuum deposition, ink-jet printing, laser induced thermal imaging, photolithography, organic vapor phase deposition (OVPD) and the like can be used to form the emission layer. The thickness of the emission layer may be about 100 to about 800 Å. When the thickness of the emission layer is less than 100 Å, efficiency and lifetime thereof is reduced. When the thickness of the emission layer is greater than 800 Å, driving voltage is increased.

A hole blocking layer (HBL) may be optionally formed by depositing a material for forming the HBL on the emission layer using vacuum deposition or spin coating as described above. The material for forming the HBL is not particularly limited, but may be a material having an electron transporting ability and higher ionized potential than that of an emissive compound. Examples of the material for forming the HBL include Balq, BCP, TPBI and the like. The thickness of the hole blocking layer may be about 30 Å to about 500 Å. When the thickness of the hole blocking layer is less than 30 Å, a hole blocking characteristic is poor leading to reduced efficiency. When the thickness of the hole blocking layer is greater than 500 Å, driving voltage is increased.

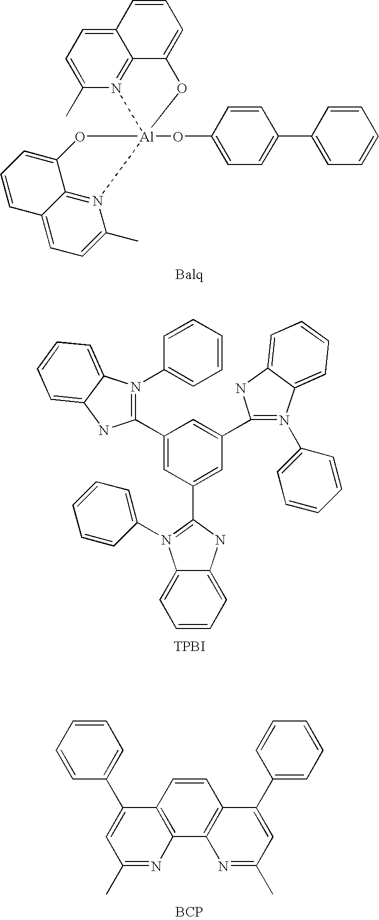

An electron transport layer (ETL) may be formed on the hole blocking layer using vacuum deposition or spin coating. The material for the electron transport layer is not particularly limited and can be Alq3. The thickness of the electron transport layer may be about 50 Å to about 600 Å. When the thickness of the electron transport layer is less than 50 Å, lifetime of the device is reduced. When the thickness of the electron transport layer is greater than 600 Å, driving voltage is increased.

In addition, an electron injection layer (EIL) can be optionally formed on the electron transport layer. Materials for forming the electron injection layer can be LiF, NaCl, CsF, Li₂O, BaO, Liq and the like. The thickness of the electron injection layer may be about 1 Å to about 100 Å. When the thickness of the electron injection layer is less than 1 Å, it can not effectively act as an electron injection layer. When the thickness of the electron injection layer is greater than 100 Å, it acts as an insulation layer, thereby having a high driving voltage.

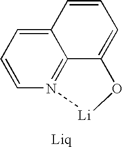

Subsequently, a cathode (or a second electrode) may be formed by depositing a metal for forming the cathode on the electron injection layer. The cathode may be formed using vacuum thermal deposition, sputtering, metal-organic chemical vapor deposition and the like. Examples of the metal for forming the cathode include, but are not limited to, lithium (Li), magnesium (Mg), aluminum (Al), aluminum-lithium (Al—Li), calcium (Ca), magnesium-indium (Mg—In), and magnesium-silver (Mg—Ag).

As described above, the organic luminescence display device according to the current embodiment includes an anode, a first hole injection layer, a charge generation layer, a second hole injection layer, a hole transport layer, an emission layer, an electron transport layer, an electron injection layer and a cathode. The device may further include an intermediate layer between two of the foregoing layers. The device may further include an electron blocking layer between the emission layer and the hole transport layer.

Hereinafter, the instant disclosure will be described in further detail with reference to the following examples. These examples are for illustrative purposes only and are not intended to limit the scope of the invention.

### EXAMPLE 1

A 15 Ω/cm² (1200 Å) Coming ITO glass substrate (available from Coming, Inc., Corning, N.Y.) as an anode was cut to be 50 mm×50 mm×0.7 mm and washed with ultrasonic waves for 5 minutes each in isopropyl alcohol and pure water, respectively, and then cleaned with UV and ozone for 30 minutes.

m-MTDATA was vacuum deposited on the substrate to form a 1,300 Å thick first hole injection layer. Hexaazatriphenylene as a material for forming a charge generation layer was deposited on the first hole injection layer to a thickness of 20 Å using resistance thermal vapor deposition. Copper m-MTDATA was vacuum deposited on the charge generation layer to form a 200 Å thick second hole injection layer. N,N′-di(1-naphthyl)-N,N′-diphenyl benzidine (α-NPD) was vacuum deposited on the second hole injection layer to form a 200 Å thick hole transport layer.

An emission layer having a thickness of about 400 Å was formed using organic vapor phase deposition (OVPD). An electron transporting material, Alq3 was deposited on the emission layer to form a 300 Å thick electron transport layer. 10 Å of LiF (electron injection layer) and 200 Å of a Mg—Ag alloy (cathode) were sequentially vacuum deposited on the electron transport layer to form a LiF/Al electrode, and thus an organic luminescence display device was completed.

### EXAMPLE 2

An organic luminescence display device was manufactured in the same manner as in Example 1, except that the thickness of a charge generation layer was 50 Å.

### EXAMPLE 3

An organic luminescence display device was manufactured in the same manner as in Example 1, except that a thickness of a charge generation layer was 80 Å.

### COMPARATIVE EXAMPLE 1

A 15 Ω/cm² (1200 Å) Corning ITO glass substrate as an anode was cut to be 50 mm×50 mm×0.7 mm and washed with ultrasonic waves for 5 minutes each in isopropyl alcohol and pure water, respectively, and then cleaned with UV and ozone for 30 minutes.

m-MTDATA was vacuum deposited on the substrate to form a 1,500 Å thick hole injection layer. N,N′-di(1-naphthyl)-N,N′-diphenyl benzidine (α-NPD) was vacuum deposited on the hole injection layer to form a 200 Å thick hole transport layer.

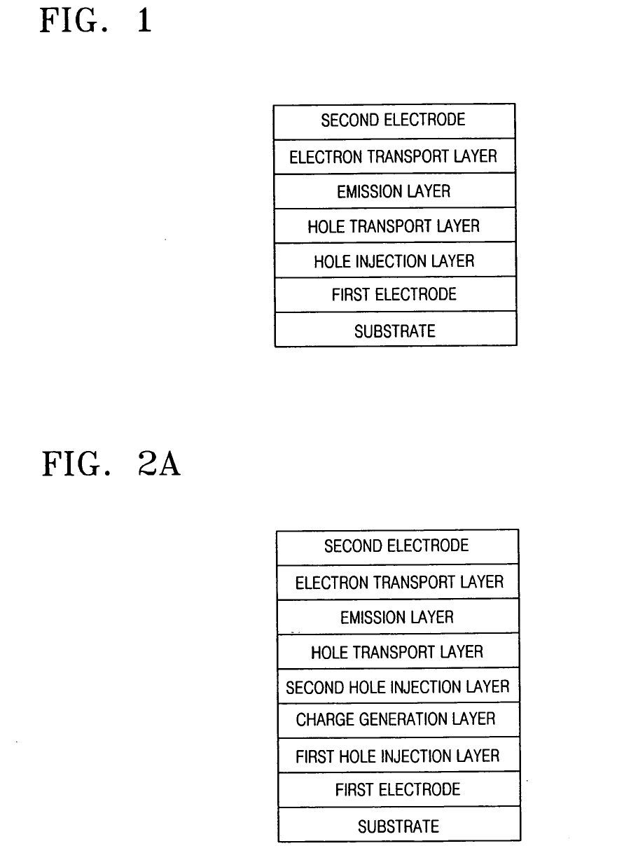

An emission layer having a thickness of about 400 Å was formed using organic vapor phase deposition (OVPD). An electron transporting material, Alq3 was deposited on the emission layer to form a 300 Å thick electron transport layer. 10 Å of LiF (electron injection layer) and 200 Å of Mg—Ag alloy (cathode) were sequentially vacuum deposited on the electron transport layer to form an LiF/Al electrode, and thus an organic luminescence display device as illustrated in FIG. 1 was manufactured.

Driving voltages, efficiencies and lifetimes of the organic luminescence display devices manufactured according to Examples 1 through 3 and Comparative Example 1 were measured, and the results are shown in Table 1 below.

TABLE 1

| | Driving voltage (V) | Efficiency (cd/A) | Lifetime (hour) |
|---|---|---|---|
| Example 1 | 5.73 | 27.18 | 1,500 |
| Example 2 | 5.71 | 26.90 | 1,500 |
| Example 3 | 5.60 | 26.85 | 1,500 |
| Comparative | 7.59 | 26.79 | 1,000 |
| Example 1 | | | |

In Examples 1 through 3, the driving voltages are 5.73-5.60 V, and in Comparative Example 1, the driving voltage is 7.59 V. In addition, in Examples 1 through 3, the efficiencies are 27.18-26.90 cd/A at a brightness of 1,900 cd/m², and in Comparative Example 1, the efficiency is 26.85 cd/A at a brightness of 1,900 cd/m².

In addition, the lifetime is defined as time taken for brightness to be reduced to 50% of the initial brightness. In Examples 1 through 3, the lifetimes are about 1,500 hours at 9,500 cd/m², and in Comparative Example 1, the lifetime is about 1,000 hours at 9,500 cd/m². As a result, it can be seen that the lifetimes of Examples 1-3 are about 1.5 times that of Comparative Example 1.

The organic luminescence display device according to the present disclosure includes a charge generation layer, thereby reducing driving voltage organic luminescence display device and improving efficiency and lifetime thereof.

While the instant disclosure has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic luminescence display device comprising:
a first electrode;
a second electrode;
an emission layer interposed between the first and second electrodes;
a first hole injection layer interposed between the first electrode and the emission layer;
a second hole injection layer interposed between the first hole injection layer and the emission layer; and
a charge generation layer interposed between the first hole injection layer and the second hole injection layer, the charge generation layer being doped with a p-type dopant.

2. The organic luminescence display device of claim 1, wherein the charge generation layer comprises a compound represented by Formula 1: 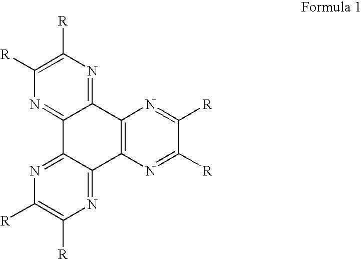
wherein R is a nitrile (—CN) group, a sulfone (—SO₂R′) group, a sulfoxide (—SOR′) group, a sulfoneamide (—SO₂NR′₂) group, a sulfonate (—SO₃R′) group, a nitro (—NO₂) group, or a trifluoromethyl (—CF₃) group; and
wherein R′ is an alkyl group, aryl group, or heterocyclic group that has 1-60 carbon atoms and is unsubstituted or substituted with amine, amide, ether, or ester.

3. The organic luminescence display device of claim 1, wherein the p-type dopant comprises at least one selected from the group consisting of hexanitrile hexaazatriphenylene, tetrafluoro-tetracyanoquinodimethane (F₄-TCNQ), FeCl₃, F₁₆CuPc and a metal oxide.

4. The organic luminescence display device of claim 3, wherein the metal oxide comprises at least one selected from the group consisting of vanadium oxide (V₂O₅), rhenium oxide (Re₂O₇), and indium tin oxide (ITO).

5. The organic luminescence display device of claim 1, wherein the p-type dopant has a lowest unoccupied molecular orbital (LUMO) energy level, wherein at least one of the first and second hole injection layers comprises a material having a highest occupied molecular orbital (HOMO) energy level, and wherein a difference between the lowest unoccupied molecular orbital (LUMO) energy level of the p-type dopant and the highest occupied molecular orbital (HOMO) energy level of the material of the at least one of the first and second hole injection layers is between about −2 eV and about +2 eV.

6. The organic luminescence display device of claim 1, wherein the device comprises a plurality of pixels, and wherein the charge generation layer forms a common layer for at least two of the pixels.

7. The organic luminescence display device of claim 1, wherein the charge generation layer has a thickness of about 10 Å to about 200 Å.

8. The organic luminescence display device of claim 1, wherein the charge generation layer has a thickness of about 20 Å to about 80 Å.

9. The organic luminescence display device of claim 1, further comprising a hole transport layer interposed between the first electrode and the emission layer, and at least one of a hole blocking layer, an electron transport layer and an electron injection layer interposed between the emission layer and the second electrode.

10. The organic luminescence display device of claim 1, further comprising an electron transport layer interposed between the second electrode and the emission layer.

11. The organic luminescence display device of claim 10, further comprising a substrate, wherein the first electrode is formed over the substrate.

12. The organic luminescence display device of claim 11, further comprising an electron injection layer interposed between the electron transport layer and the second electrode.

13. The organic luminescence display device of claim 12, further comprising a hole blocking layer interposed between the electron transport layer and the emission layer.

14. An electronic device comprising the organic luminescence display device of claim 1.

15. A method of manufacturing an organic luminescence display device, the method comprising:
forming a first hole injection layer over a first electrode;
forming a charge generation layer over the first hole injection layer, the charge generation layer being doped with a p-type dopant; and
forming a second hole injection layer over the charge generation layer.

16. The method of claim 15, further comprising:
forming an emission layer over the second hole injection layer; and
forming a second electrode over the emission layer.

17. The method of claim 16, further comprising:
forming a hole transport layer after forming the second hole injection layer and before forming the emission layer; and
forming at least one of a hole blocking layer, an electron transport layer, and an electron injection layer after forming the emission layer and before forming the second electrode.

18. The method of claim 15, wherein the charge generation layer comprises a compound represented by Formula 1: 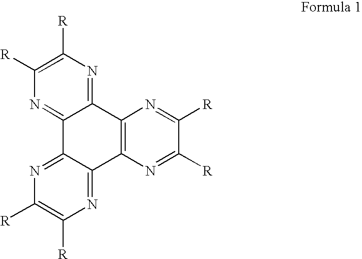
wherein R is a nitrile (—CN) group, a sulfone (—SO₂R′) group, a sulfoxide (—SOR′) group, a sulfoneamide (—SO₂NR′₂) group, a sulfonate (—SO₃R′) group, a nitro (—NO₂) group, or a trifluoromethyl (—CF₃) group; and
wherein R′ is an alkyl group, aryl group, or heterocyclic group that has 1-60 carbon atoms and is unsubstituted or substituted with amine, amide, ether, or ester.

19. The method of claim 15, wherein the p-type dopant comprises at least one selected from the group consisting of hexanitrile hexaazatriphenylene, tetrafluoro-tetracyanoquinodimethane (F₄-TCNQ), FeCl₃, F₁₆CuPc and a metal oxide.

20. The method of claim 19, wherein the metal oxide is at least one selected from the group consisting of vanadium oxide (V₂O₅), rhenium oxide (Re₂O₇), and indium tin oxide (ITO).

21. The method of claim 15, wherein the p-type dopant has a lowest unoccupied molecular orbital (LUMO) energy level, wherein at least one of the first and second hole injection layers comprises a material having a highest occupied molecular orbital (HOMO) energy level, and wherein a difference between the lowest unoccupied molecular orbital (LUMO) energy level of the p-type dopant and the highest occupied molecular orbital (HOMO) energy level of the material of the at least one of the first and second hole injection layers is between about −2 and about +2 eV.

22. The method of claim 15, wherein forming the charge generation layer comprises using resistance heating vapor deposition, electron beam vapor deposition, laser beam vapor deposition, or sputtering deposition.

23. The method of claim 15, wherein the charge generation layer has a thickness of about 10 Å to about 200 Å.
